(19) United States
(12) Patent Application Publication
(10) Pub. No.: US 2005/0189164 A1
(43) Pub. Date: Sep. 1, 2005

(54) Speaker enclosure having outer flared tube

(76) Inventor: Chi Lung Chang, Taichung (TW)

Correspondence Address: Chi Lung Chang, P.O. Box 63-298, Taichung, 406, TW

(21) Appl. No.: 10/789,796

(22) Filed: Feb. 26, 2004

(51) Int. Cl. H05K 5/00

(52) U.S. Cl. 181/152; 181/156

(57) ABSTRACT

A speaker enclosure includes a housing having a chamber formed by a front panel, a rear panel and an upper panel, to receive one or more speakers. The housing includes an opening formed in the rear panel. A flared tube is disposed outside of the housing, and includes one end attached to the opening of the rear panel of the housing, to enclose the opening of the rear panel of the housing, and to prevent dirt or bugs or insets from entering into the speaker enclosure via the opening of the rear panel of the housing. The flared tube includes a flared member to direct sound out of the housing, preferably forwardly of the housing.

### BACKGROUND OF THE INVENTION

1. Field of the Invention

The present invention relates to a speaker enclosure, and more particularly to a speaker enclosure having a flared tube extended outwardly thereof.

2. Description of the Prior Art

Typical speaker devices comprise an enclosure, and one or more diaphragms and other elements received within the enclosure. Normally, the typical speaker devices comprise one or more openings formed in the rear portion of the enclosure, for such as sound resonant purposes.

For example, U.S. Pat. No. 5,687,247 to Proni discloses one of the typical speaker devices including a pole piece received in the inner portion of a back plate to form or define a pole or an opening in the back plate, for such as sound resonant purposes. However, dirt or bugs or insets may easily enter into the speaker enclosures via the pole or the opening of the back plate.

U.S. Pat. No. 5,627,350 to Kang discloses another typical speaker device including one or more openings formed in the rear plate. However, similarly, dirt or bugs or insets may easily enter into the speaker enclosures via the pole or the opening of the back plate.

The sound quality of the speaker devices may be influenced by the dirt that enter into the speaker enclosures. In addition, the diaphragms and the other elements received within the speaker enclosures may be easily damaged by the bugs or insets.

The present invention has arisen to mitigate and/or obviate the afore-described disadvantages of the conventional speaker enclosures.

### SUMMARY OF THE INVENTION

The primary objective of the present invention is to provide a speaker enclosure including a flared tube extended outwardly thereof to enclose the rear openings of the speaker enclosure, and to prevent dirt or bugs or insets from entering into the speaker enclosures via the rear openings of the speaker enclosures.

The other objective of the present invention is to provide a speaker enclosure including a flared tube extended outwardly thereof to direct the sound outwardly of the speaker enclosure, and to increase the sound effect of the speaker enclosures.

In accordance with one aspect of the invention, there is provided a speaker enclosure comprising a housing including a chamber formed therein and defined by a front panel, a rear panel and an upper panel, the rear panel including an opening formed therein and communicating with the chamber of the housing, at least one speaker received in the chamber of the housing, and attached to the front panel, and a flared tube disposed outside of the housing. The flared tube includes a first end attached to the opening of the rear panel of the housing, to enclose the opening of the rear panel of the housing, to prevent dirt or bugs or insets from entering into the speaker enclosure via the opening of the rear panel of the housing. The flared tube includes a second end having a flared member attached thereto to direct sound out of the housing, preferably to direct the sound out of the housing forwardly.

The opening of the rear panel of the housing is aligned with the speaker. The speaker is preferably a low frequency speaker.

The flared tube includes a straight segment disposed outside of the rear panel of the housing, and secured to the rear panel of the housing. The flared tube includes at least one bracket to secure the straight segment to the rear panel of the housing. The flared tube includes a lateral segment extended from the straight segment, the flared member is attached to the lateral segment of the flared tube. The lateral segment of the flared tube is preferably disposed above the upper panel of the housing.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a perspective view of a speaker enclosure in accordance with the present invention; and

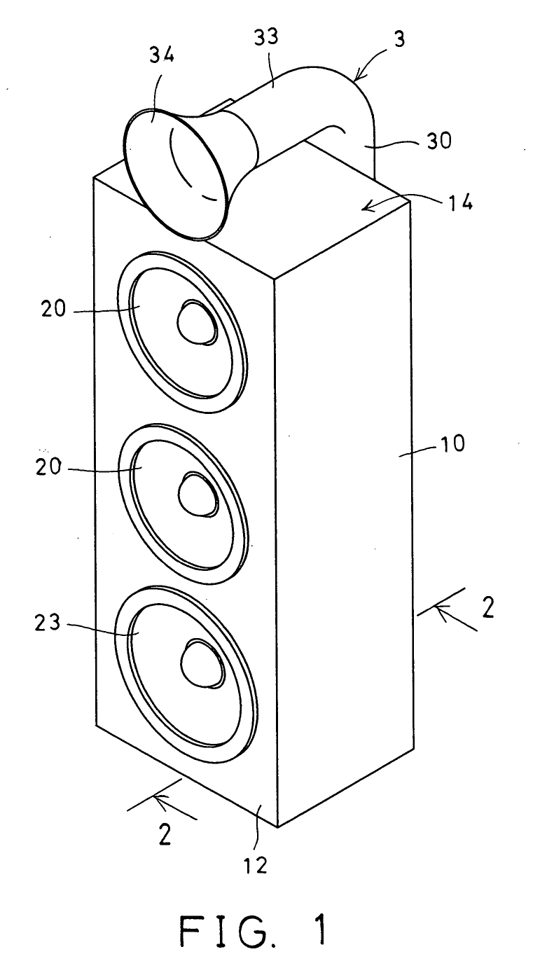

FIG. 2 is a cross sectional view of the speaker enclosure, taken along lines 2-2 of FIG. 1.

### DETAILED DESCRIPTION OF THE PREFERRED EMBODIMENT

Referring to the drawings, a speaker enclosure in accordance with the present invention comprises a housing 10 including a chamber 11 provided or formed therein and defined by a front panel 12, a rear panel 13 and an upper panel 14. The front panel 12 includes one or more pores 15 formed therein and communicating with the chamber 11 of the housing 10, and the rear panel 13 includes one or more openings 16 formed therein and communicating with the chamber 11 of the housing 10.

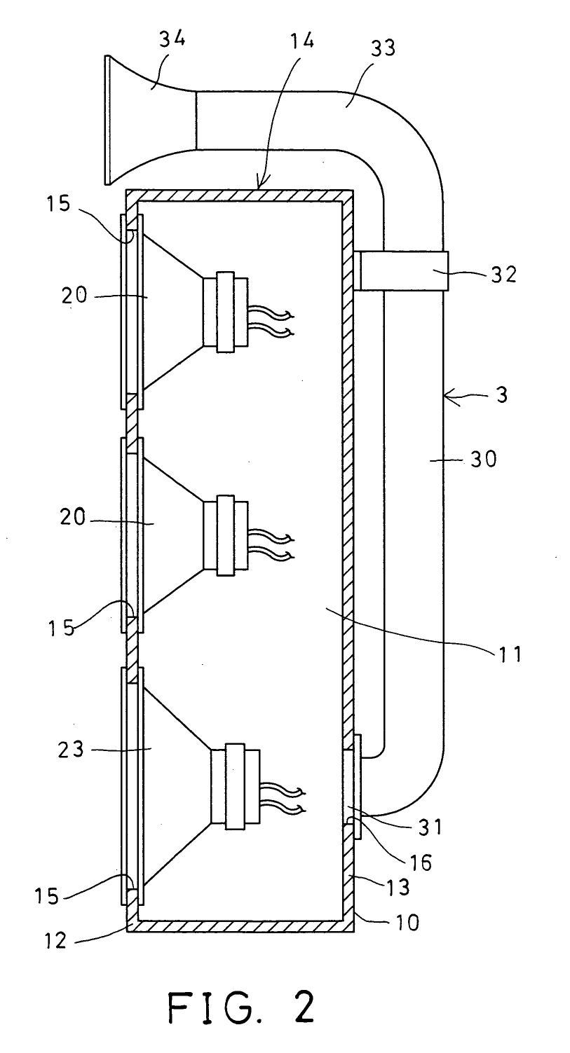

One or more audio speakers 20 are received in the chamber 11 of the housing 10, and engaged in the respective pores 15 of the front panel 12 of the housing 10. One or more low frequency speakers or woofers 23 may further be provided and also received in the chamber 11 of the housing 10, and engaged in the respective pores 15 of the front panel 12 of the housing 10. It is preferable that the low frequency speakers or woofers 23 are arranged or aligned with the respective openings 16 of the rear panel 13 of the housing 10, best shown in FIG. 2.

The speaker enclosure further includes a flared tube 3 attached to the housing 10 and extended outwardly of the housing 10, to direct the sound outwardly of the housing 10, and to increase the sound effect of the speaker enclosures.

As shown in FIG. 2, the flared tube 3 includes one end 31 engaged into or attached to the opening 16 of the rear panel 13 of the housing 10, and includes a straight segment 30 disposed outside of the housing 10, and secured to the rear panel 13 of the housing 10 with one or more fasteners or brackets 32, and includes a lateral segment 33 curved or bent or extended or inclined relative to the straight segment 30, or perpendicular to the straight segment 30, and preferably disposed above the upper panel 14 of the housing 10, and includes a flared member 34 attached to the front portion of the lateral segment 33.

It is preferable that the flared member 34 of the flared tube 3 is directed toward the front portion of the housing 10 or directed forwardly, for transmitting the sound forwardly of the housing 10 and toward the users, such that the sound effect or the sound quality of the speaker enclosure may be facilitated. In addition, the end 31 of the flared tube 3 may enclose or block the opening 16 of the rear panel 13 of the housing 10, to prevent dirt or bugs or insets from entering into the housing 10 via the opening 16 of the rear panel 13 of the housing 10.

Accordingly, the speaker enclosure in accordance with the present invention includes a flared tube extended outwardly thereof to enclose the rear openings of the speaker enclosure, and to prevent dirt or bugs or insets from entering into the speaker enclosures via the rear openings of the speaker enclosures, and to direct the sound outwardly of the speaker enclosure, and to increase the sound effect of the speaker enclosures.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

1. A speaker enclosure comprising:
a housing including a chamber formed therein and defined by a front panel, a rear panel and an upper panel, said rear panel including an opening formed therein and communicating with said chamber of said housing,
at least one speaker received in said chamber of said housing, and attached to said front panel, and
a flared tube disposed outside of said housing, and including a first end attached to said opening of said rear panel of said housing, to enclose said opening of said rear panel of said housing, and including a second end having a flared member attached thereto to direct sound out of said housing.

2. The speaker enclosure as claimed in claim 1, wherein said opening of said rear panel of said housing is aligned with said speaker.

3. The speaker enclosure as claimed in claim 2, wherein said speaker is a low frequency speaker.

4. The speaker enclosure as claimed in claim 1, wherein said flared tube includes a straight segment disposed outside of said rear panel of said housing, and secured to said rear panel of said housing.

5. The speaker enclosure as claimed in claim 4, wherein said flared tube includes at least one bracket to secure said straight segment to said rear panel of said housing.

6. The speaker enclosure as claimed in claim 4, wherein said flared tube includes a lateral segment extended from said straight segment, said flared member is attached to said lateral segment of said flared tube.

7. The speaker enclosure as claimed in claim 6, wherein said lateral segment of said flared tube is disposed above said upper panel of said housing.
